(19) United States
(12) Patent Application Publication
(10) Pub. No.: US 2012/0153373 A1
(43) Pub. Date: Jun. 21, 2012

(54) GATE STRUCTURE

(75) Inventor: Jyun-Huan Chen, Taipei City (TW)

(73) Assignee: NANYA TECHNOLOGY CORPORATION, Taoyuan (TW)

(21) Appl. No.: 12/969,596

(22) Filed: Dec. 16, 2010

(51) Int. Cl. H01L 29/788

(52) U.S. Cl. 257/315; 257/411; 257/E29.3

(57) ABSTRACT

A gate structure is described, including a dielectric layer, a gate conductive layer and a stacked cap structure. The dielectric layer is disposed between a substrate and the gate conductive layer. The gate conductive layer is disposed between the dielectric layer and the stacked cap structure. The stacked cap structure disposed on the gate conductive layer includes at least two insulating layers having different materials and contacting each other.

### BACKGROUND OF THE INVENTION

1. Field of Invention

This invention relates to a gate structure, and more particularly relates to a gate capable of inhibiting RC delay.

2. Description of Related Art

In some advanced semiconductor processes forming metal gates, the cap layer on the metal gates serves as a polishing stopper of the contact conductive layer during the contact formation process. Hence, the cap layer usually includes silicon nitride (SiN) that has a lower polishing selectivity than the inter-layer dielectric layer. However, for the dielectric constant of SiN is up to 7 and the device dimensions are quite small, the parasitic capacitance between the gate and the contacts at two sides thereof is large and gets larger as the gate width is reduced more to cause a significant RC delay problem.

### SUMMARY OF THE INVENTION

Accordingly, this invention provides a gate structure that is capable of reducing the parasitic capacitance between the gate and the contacts and inhibiting the RC delay.

The gate structure of this invention includes a gate conductive layer over a substrate, a dielectric layer between the gate conductive layer and the substrate, and a stacked cap structure over the gate conductive layer. The stacked cap structure includes at least two insulating layers including different insulating materials and contacting each other.

With the above stacked cap structure, the gate structure is capable of reducing the parasitic capacitance between the gate and the contacts and inhibiting the RC delay.

In order to make the aforementioned and other objects, features and advantages of this invention comprehensible, a preferred embodiment accompanied with figures is described in detail below.

### BRIEF DESCRIPTION OF THE DRAWINGS

FIG. 1 schematically illustrates a cross section of a gate structure according to an embodiment of this invention.

FIGS. 2A-2H schematically illustrate, in a cross-sectional view, a process for fabricating a MOS transistor according to an embodiment of this invention.

### DESCRIPTION OF EMBODIMENTS

This invention is further explained utilizing the following embodiment and the accompanying drawings, which are not intended to limit the scope of this invention.

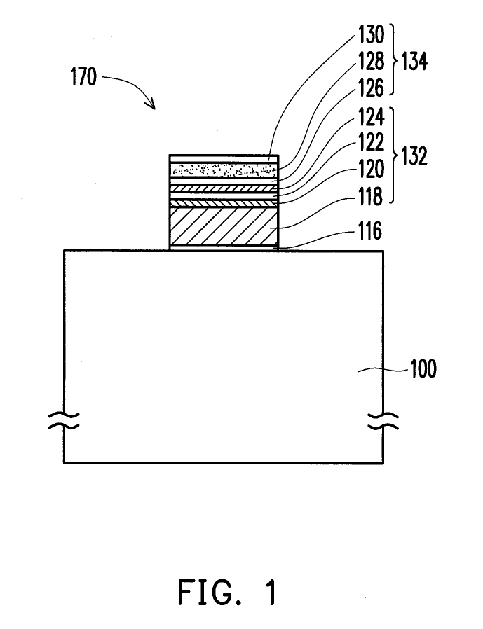

FIG. 1 schematically illustrates a cross section of a gate structure according to an embodiment of this invention.

Referring to FIG. 1, the gate structure 170 includes, from bottom to top, a dielectric layer 116, a gate conductive layer 132 and a stacked cap structure 134.

The dielectric layer 116 is disposed on the substrate 100, possibly including silicon oxide, SiN, or a high-k dielectric material with a dielectric constant above 7.

The gate conductive layer 132 is between the dielectric layer 116 and the stacked cap structure 134. The gate conductive layer 132 may consist of a single material layer or include two or more layers with different materials. The single material layer may be a doped semiconductor layer. The different materials of the two or more layers may be selected from doped semiconductor materials, metal materials, metal nitrides and combinations thereof. In an embodiment, the gate conductive layer 132 includes a doped semiconductor layer 118, a first metal layer 120, a metal nitride layer 122 and a second metal layer 124. The doped semiconductor layer 118 may be a doped poly-Si layer, the first metal layer 120 may be a titanium layer or a titanium silicide layer. The metal nitride layer 122 may be a tungsten nitride layer or a titanium nitride layer. The second metal layer 124 may be a tungsten layer.

The stacked cap structure 134 includes at least two insulating layers including different insulating materials and contacting each other. The insulating materials in the stacked cap structure 134 have different dielectric constants, which may range from 4 to 7. In an embodiment, the stacked cap structure 134 include a first insulating layer 126 on the gate conductive layer 132, and a second insulating layer 128 on the first insulating layer 126. The thickness of the second insulating layer 128 is larger than that of the first insulating layer 126. The dielectric constant of the second insulating layer 128 is lower than that of the first insulating layer 126.

Moreover specifically, the atomic composition of the second insulating layer 128 includes the compositional atoms of the first insulating layer 126, and dopant atoms that make the dielectric constant of the second insulating layer 128 lower than that of the first insulating layer 126 to reduce the parasitic capacitance caused by the stacked cap structure 134 and inhibit RC delay. The first insulating layer 126 can serve as a barrier layer for blocking diffusion of the dopant atoms from the second insulating layer 128 to the gate conductive layer 132. For example, the first insulating layer 126 is an SiN layer while the dopant atoms in the second insulating layer 128 may include carbon, fluorine, oxygen, or a combination thereof. That is, the second insulating layer 128 may include C-doped SiN, F-doped SiN, O-doped SiN, or a combination thereof.

In the second insulating layer 128, the molar ratio of the dopant atoms to the nitrogen atoms may range from 0.1 to 3. The first insulating layer 126 may be formed with CVD, and may have a thickness of about 50 angstroms. The second insulating layer 128 may also be formed with CVD, and may have a thickness of about 1300 angstroms.

In another embodiment, in addition to the first and second insulating layers 126 and 128, the stacked cap structure 134 further includes a third insulating layer 130 on the second insulating layer 128. The material or the forming method of the third insulating layer 130 may be the same as or different from that of the first insulating layer 126. The thickness of the first insulating layer 126 may range from 30 angstroms to 100 angstroms. The thickness of the second insulating layer 128 may range from 1000 angstroms to 1200 angstroms. The thickness of the third insulating layer 130 may range from 50 angstroms to 100 angstroms.

The above gate structure 170 may be applied to a metal oxide semiconductor (MOS) transistor. That is, the dielectric layer 116, the gate conductive layer 132 and the stacked cap structure 134 in the gate structure 170 may respectively serve as a gate dielectric layer, a gate conductive layer and a stacked cap structure of a MOS transistor. The gate structure 170 may alternatively be applied to a flash memory cell as a split-gate structure. More specifically, the dielectric layer 116, the gate conductive layer 132 and the stacked cap structure 134 in the gate structure 170 may respectively serve as a gate dielectric layer, a split-gate conductive layer and a stacked cap structure of a flash memory cell.

The application of the gate structure of this invention is further described below, with the following fabricating process of a MOS transistor as an example.

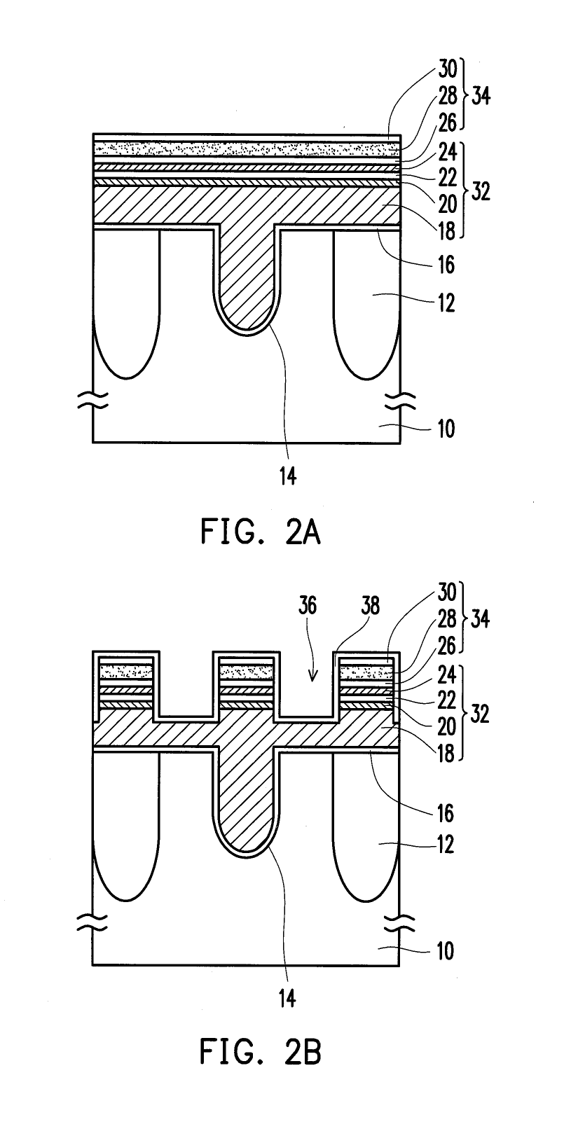

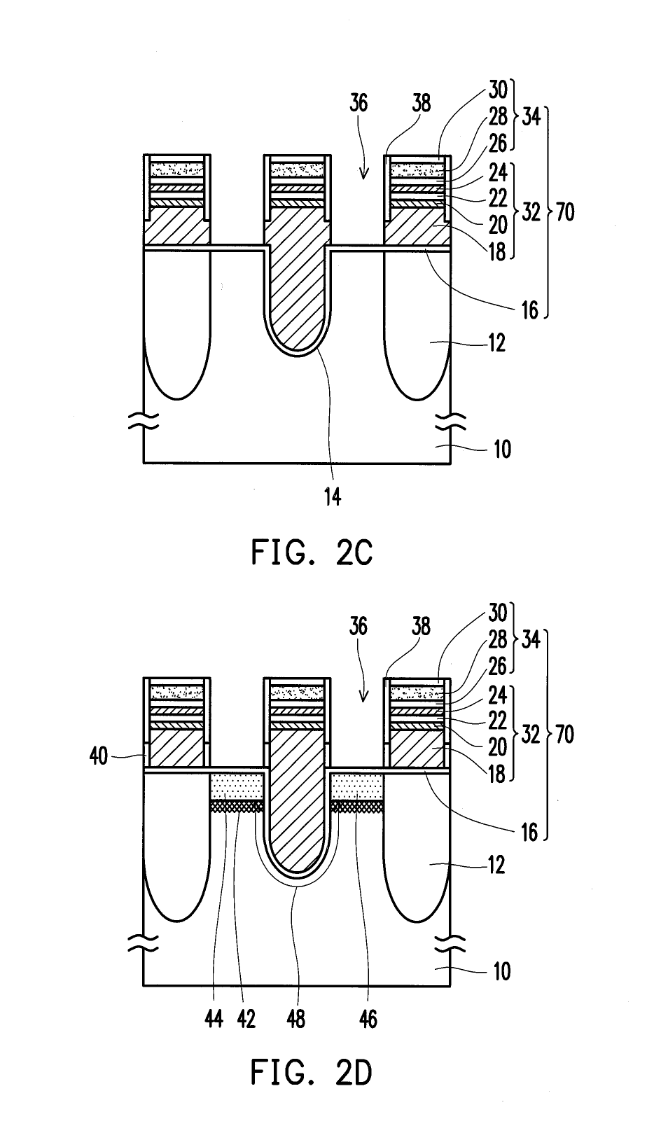

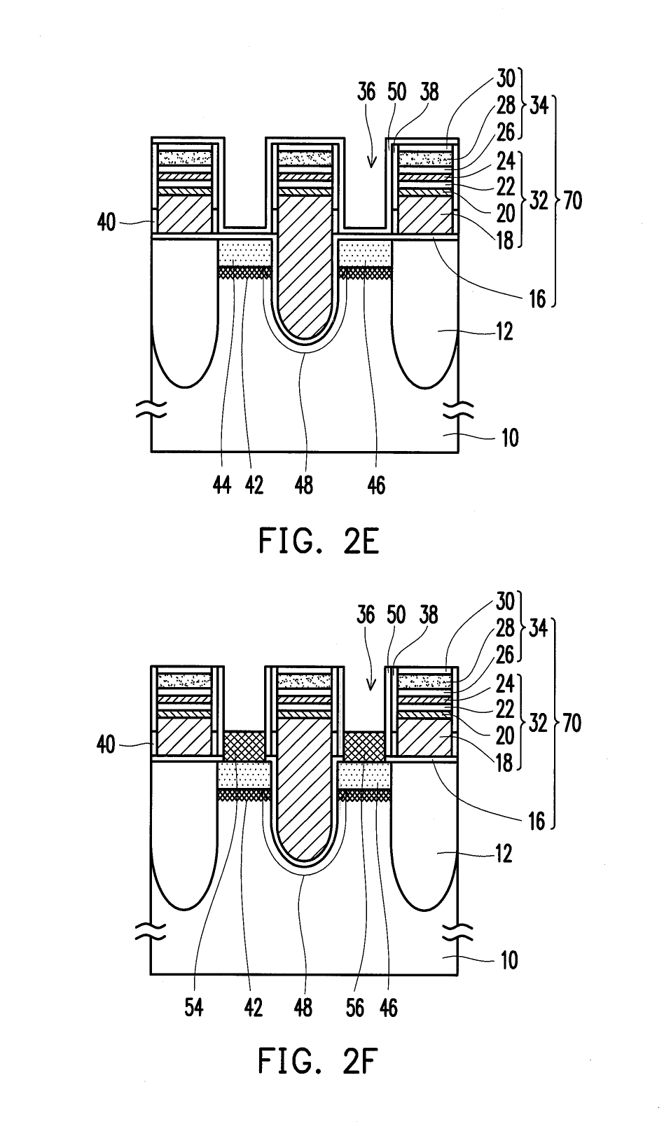

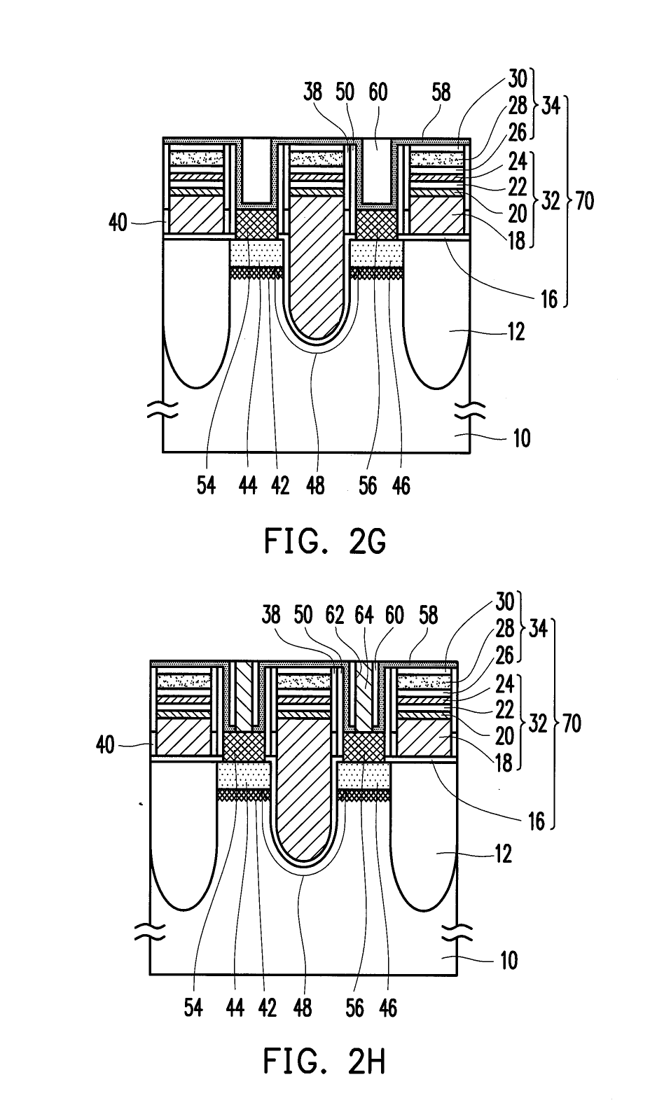

FIGS. 2A-2H schematically illustrate, in a cross-sectional view, a process for fabricating a MOS transistor according to an embodiment of this invention.

Referring to FIG. 2A, an isolation structure 12 is formed in the substrate 10, which may be a doped semiconductor substrate that may be P-doped or N-doped. The isolation structure 12 may be a shallow trench isolation (STI) structure.

A trench 14 is then formed in the substrate 10, and a dielectric layer 16 is formed in trench 14 and on the substrate 10. The step of forming the trench 14 in the substrate 10 includes, e.g., lithographically defining a to-be-etched portion of the substrate 10 and etching the same. The dielectric layer 16 may include silicon oxide, SiN or a high-k material with a dielectric constant more than 7. When the dielectric layer 16 includes silicon oxide, for example, it may be formed through thermal oxidation and may have a thickness of about 30 angstroms.

A gate conductive layer 32 is then formed in the trench 14 and on the substrate 10. The gate conductive layer 32 may include a stack of conductive material layers, such as a stack of a doped semiconductor layer 18, a first metal layer 20, a metal nitride layer 22 and a second metal layer 24. The doped semiconductor layer 18 may be a doped poly-Si layer, may be formed with CVD, and may have a thickness of about 800 angstroms. The first metal layer 20 may be a titanium layer or a titanium silicide layer, may be formed with CVD, and may have a thickness of about 80 angstroms. The metal nitride layer 22 may be a tungsten nitride layer or a titanium nitride layer, may be formed with CVD, and may have a thickness of about 200 angstroms. The second metal layer 24 may be a tungsten layer or a tantalum layer, may be formed with CVD, and may have a thickness of about 300 angstroms. For the convenience of illustration, the gate conductive layer 32 including a stack of a doped semiconductor layer 18, a first metal layer 20, a metal nitride layer 22 and a second metal layer 24 is taken as an example to describe the gate conductive layer in this embodiment.

A stacked cap structure 34 is then formed on the second metal layer 24. The stacked cap structure 34 includes at least two insulating layers having different materials and contacting each other. The different insulating materials constituting the stacked cap structure 34 have different dielectric constants that may range from 4 to 7.

In an embodiment, the stacked cap structure 34 includes a first insulating layer 26 disposed on the gate conductive layer 32, and a second insulating layer 28 disposed on the first insulating layer 26 and having a thickness larger than that of the latter and a dielectric constant less than that of the latter.

Moreover specifically, the atomic composition of the second insulating layer 28 includes the compositional atoms of the first insulating layer 26, and dopant atoms that make the dielectric constant of the second insulating layer 28 lower than that of the first insulating layer 26 to reduce the parasitic capacitance caused by the stacked cap structure 34 and inhibit RC delay. The first insulating layer 26 can serve as a barrier layer for blocking diffusion of the dopant atoms from the second insulating layer 28 to the gate conductive layer 32. For example, the first insulating layer 126 is an SiN layer while the dopant atoms in the second insulating layer 128 may include carbon, fluorine, oxygen, or a combination thereof. That is, the second insulating layer 128 may include C-doped SiN, F-doped SiN, O-doped SiN, or a combination thereof.

In the second insulating layer 28, the molar ratio of the dopant atoms to the nitrogen atoms may range from 0.1 to 3. The first insulating layer 26 may be formed with CVD, and may have a thickness of about 50 angstroms. The second insulating layer 128 may be formed by CVD, and may have a thickness of about 1300 angstroms.

In another embodiment, in addition to the first and second insulating layers 26 and 28, the stacked cap structure 34 further includes a third insulating layer 30 on the second insulating layer 28. The material or the forming method of the third insulating layer 30 may be the same as or different from that of the first insulating layer 26. The thickness of the first insulating layer 26 may range from 30 angstroms to 100 angstroms. The thickness of the second insulating layer 28 may range from 1000 angstroms to 1200 angstroms. The thickness of the third insulating layer 30 may range from 50 angstroms to 100 angstroms.

Referring to FIG. 2B, the stacked cap structure 34, the second metal layer 24, the metal nitride layer 22, the first metal layer 20 and a portion of the doped semiconductor layer 18 are patterned in sequence to form openings 36 that expose portions of the remaining doped semiconductor layer 18. By forming the openings 36 into the doped semiconductor layer 18, the second metal layer 24, the metal nitride layer 22 and the first metal layer 20 can be protected by the mask layer 38 formed later.

A mask layer 38 is then formed on the substrate 10, covering the stacked cap structure 34 and the portions of the doped semiconductor layer 18, the first metal layer 20, the metal nitride layer 22 and the second metal layer 24 exposed by the openings 36. The mask layer 38 may include SiN or SiCN, may be formed with CVD, and may have a thickness of 60-100 angstroms.

Referring to FIG. 2C, the portions of the mask layer 38 and the remaining doped semiconductor layer 18 at bottoms of the openings 36 are removed to expose portions of the dielectric layer 16 and the sidewalls of the remaining doped semiconductor layer 18, thus finishing the fabrication of a gate structure 70. The removal step may include removing the portions of the mask layer 38 with a dry etching recipe and removing the portions of the doped semiconductor layer 18 with another dry etching recipe. When the portions of the mask layer 38 at the bottoms of the openings 36 are removed, the portions of the same above the stacked cap structure 34 are also removed.

The resulting gate structure 70 includes, from bottom to top, the dielectric layer 16, the gate conductive layer 32 and the stacked cap structure 34. The stacked cap structure 34 at least includes the first insulating layer 26 and the second insulating layer 28. The gate conductive layer 32 includes a stack of, from bottom to top, the doped semiconductor layer 18 partially in the trench 14 and extending to above the substrate 10, the first metal layer 20, the metal nitride layer 22 and the second metal layer 24.

Referring to FIG. 2D, an oxidation process, such as a thermal oxidation process, is done with the mask layer 38 as a mask, so that a portion of the doped semiconductor layer 18 exposed by the openings 36 are oxidized into an oxide layer 40 to improve the device functionality. In an embodiment, the doped semiconductor layer 18 includes doped poly-Si, and a portion thereof exposed by the openings 36 is converted to silicon oxide in the oxidation process.

Thereafter, a first ion implant process forming pocket doped regions 42 in the substrate 10 and a second ion implant process forming lightly doped source/drain (S/D) regions 44 and 46 in the substrate 10 are performed. The channel region 48 of the MOS transistor is between the lightly doped S/D regions 44 and 46. When the dopant implanted in the first implant process has a first conductivity type, the dopant implanted in the second implant process is of a second conductivity type. In an embodiment, the first conductivity type is P-type and the second conductivity type is N-type. In another embodiment, the first conductivity type is N-type and the second conductivity type is P-type. The N-type dopant ion may be phosphorus ion or arsenic ion. The P-type dopant ion may be boron ion or boron trifluoride ion.

Referring to FIG. 2E, a selectivity layer 50 is formed over the substrate 10. The selectivity layer 50 covers the mask layer 38, the oxide layer 40 and the dielectric layer 16 at the bottoms of the openings 36, and is for improving the epitaxial selectivity to the substrate 10 in the subsequent epitaxy process. The selectivity layer 50 may include SiN or SiCN, may be formed by CVD, and may have a thickness of 130-150 angstroms.

Referring to FIG. 2F, the portions of the selectivity layer 50 and the dielectric layer 16 at the bottoms of the openings 36 are removed to expose the lightly doped S/D regions 44 and 46. The removal step may include a dry etching process, in which the portion of the selectivity layer 50 above the stacked cap structure 34 is also removed.

Thereafter, doped epitaxial silicon layers 54 and 56 are formed on the lightly doped S/D regions 44 and 46. The doped epitaxial silicon layers 54 and 56 may be formed with CVD, and may have a thickness of 150-300 angstroms. The doped epitaxial silicon layers 54 and 56 serve as a source region and a drain region, of which the dopant concentration is higher than that of the lightly doped S/D regions 44 and 46 to reduce the contact resistance between the lightly doped S/D region 44 or 46 and the contact plug formed later.

Referring to FIG. 2G, a blocking layer 58 is then formed over the substrate 10, covering the selectivity layer 50, the stacked cap layer 34 and the doped epitaxial silicon layers 54 and 56. A dielectric layer 60 is then formed filling up the openings 36 above the lightly doped S/D regions 44 and 46, while the blocking layer 58 separate the doped epitaxial silicon layers 54 and 56 from the dielectric layer 60 to prevent the impurity (e.g., P, B or both) in the dielectric layer 60 from diffusing into the doped epitaxial silicon layers 54 and 56 and prevent the gas (e.g., oxygen) for forming the dielectric layer 60 from diffusing into the doped epitaxial silicon layers 54 and 56 and reacting with the same. The blocking layer 58 may include SiN or SiCN, may be formed with CVD, and may have a thickness of 40-70 angstroms. The dielectric layer 60 may include silicon dioxide, phosphosilicate glass (PSG), borosilicate glass (BSG) or borophosphosilicate glass (BPSG), and may be formed with CVD. The step of forming the dielectric layer 60 may include: depositing over the substrate 10 a dielectric material covering the blocking layer 58 and filling up the openings 36 above the lightly doped S/D regions 44 and 46, and removing the dielectric material on the blocking layer 58. The dielectric material may be formed with CVD, and may have a thickness of 3000-4000 angstroms. The dielectric material on the blocking layer 58 may be removed with chemical mechanical polishing (CMP) or etching-back using the blocking layer 58 as a stopping layer.

Referring to FIG. 2H, contact openings 62 are formed in the dielectric layer 60 and the blocking layer 58, exposing the doped epitaxial silicon layers 54 and 56. The contact openings 62 may be formed by lithographically defining the area to be etched and then etching the same to remove a portion of the dielectric layer 60 and a portion of the blocking layer 58.

Then, contact plugs 64 are formed in the contact openings 60, coupling with the doped epitaxial silicon layers 54 and 56. The step of forming the contact plugs 64 may include: depositing over the substrate 10 a conductive material that covers the blocking layer 58 and fills up the contact openings 62, and removing the conductive material over the blocking layer 58. The conductive material may include doped poly-Si or tungsten, may be formed with CVD, and may have a thickness of 1000-1300 angstroms. The conductive material on the blocking layer 58 may be removed with CMP or etching-back using the blocking layer 58 as a stopping layer.

According to the above embodiments of this invention, the cap structure is this invention includes multiple insulating material layers. Because the insulating material layers includes a low-k material, the parasitic capacitance between the contact plugs and the gate under the cap structure can be reduced inhibiting RC delay effect.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A gate structure, comprising:
a gate conductive layer over a substrate;
a dielectric layer between the gate conductive layer and the substrate; and
a stacked cap structure over the gate conductive layer, comprising at least two insulating layers comprising different insulating materials and contacting each other.

2. The gate structure of claim 1, wherein the different insulating materials have different dielectric constants.

3. The gate structure of claim 2, wherein the dielectric constants of the insulating materials range from 4 to 7.

4. The gate structure of claim 3, wherein the insulating materials are selected from silicon nitride, silicon oxide, carbon-doped silicon nitride, fluorine-doped silicon nitride, oxygen-doped silicon nitride, and combinations thereof.

5. The gate structure of claim 1, wherein the stacked cap structure comprises:
a first insulating layer on the gate conductive layer; and
a second insulating layer on the first insulating layer,
wherein a thickness of the second insulating layer is larger than a thickness of the first insulating layer, and a dielectric constant of the second insulating layer is lower than a dielectric constant of the first insulating layer.

6. The gate structure of claim 5, wherein an atomic composition of the second insulating layer comprises:
compositional atoms of the first insulating layer; and
dopant atoms that make the dielectric constant of the second insulating layer lower than the dielectric constant of the first insulating layer.

7. The gate structure of claim 6, wherein the first insulating layer comprises a barrier layer for blocking diffusion of the dopant atoms from the second insulating layer to the gate conductive layer.

8. The gate structure of claim 7, wherein the first insulating layer comprises a silicon nitride layer.

9. The gate structure of claim 8, wherein the dopant atoms in the second insulating layer comprise carbon, fluorine, oxygen, or a combination thereof.

10. The gate structure of claim 9, wherein in the second insulating layer, a molar ratio of the dopant atoms to nitrogen atoms ranges from 0.1 to 3.

11. The gate structure of claim 5, wherein the stacked cap structure further comprises a third insulating layer on the second insulating layer.

12. The gate structure of claim 11, wherein the third insulating layer comprises a material the same as a material of the first insulating layer.

13. The gate structure of claim 11, wherein the third insulating layer comprises a material different from a material of the first insulating layer.

14. A metal oxide semiconductor (MOS) transistor comprising the gate structure of claim 1.

15. A flash memory cell comprising the gate structure of claim 1, wherein the gate conductive layer serves as a split-gate conductive layer, and the dielectric layer serves as a gate dielectric layer under the split-gate conductive layer.
